(19) United States
(12) Patent Application Publication
(10) Pub. No.: US 2013/0122707 A1
(43) Pub. Date: May 16, 2013

(54) METHODS OF POLYMERS DEPOSITION FOR FORMING REDUCED CRITICAL DIMENSIONS

(71) Applicants: Daisuke Shimizu, Sunnyvale, CA (US); Jong Mun Kim, San Jose, CA (US)

(72) Inventors: Daisuke Shimizu, Sunnyvale, CA (US); Jong Mun Kim, San Jose, CA (US)

(21) Appl. No.: 13/656,589

(22) Filed: Oct. 19, 2012

Related U.S. Application Data
(60) Provisional application No. 61/559,608, filed on Nov. 14, 2011.

(51) Int. Cl. H01L 21/31; H01L 21/302

(52) U.S. Cl. 438/694; 438/758; 257/E21.214; 257/E21.24

(57) ABSTRACT

Methods of polymer deposition for forming reduced critical dimensions are described. In one embodiment, a substrate is provided into a chamber, the substrate having a patterned layer disposed on an underlying layer formed thereon. The patterned layer includes a plurality of openings, each opening having a sidewall, a bottom, and a critical dimension. A gas mixture is provided into the chamber, the gas mixture having an etching gas and a polymer control gas. The polymer control gas includes a polymerizing fluorocarbon CₓF_{y} gas and a C—H bond containing gas. A plasma is formed with the gas mixture and a conformal polymer layer is deposited in the presence of the plasma on the patterned layer to form a reduced critical dimension in each opening. The reduced critical dimension is smaller than the corresponding critical dimension of the opening.

### CROSS-REFERENCE TO RELATED APPLICATIONS

This application claims the benefit of and priority to U.S. Provisional Application No. 61/559,608, filed Nov. 14, 2011, the entire contents of which are hereby incorporated by reference herein.

### BACKGROUND

1) Field

Embodiments of this invention relates to a method of polymer deposition for forming reduced critical dimensions.

2) Description of Related Art

In the fabrication of modern integrated circuits, the feature sizes are typically smaller than the lithographically printed critical dimensions (CD). The smaller feature sizes are often achieved using post-lithography ‘shrink’ methods. One conventional ‘shrink’ method involves depositing a conformal polymer layer on the sidewalls of the openings in a patterned layer where the polymer layer forms a reduced critical dimension in each opening. The polymer layer behaves like a mask where subsequent etching processes etch the underlying layers through the openings and produce features having the reduced critical dimensions.

As integrated circuit manufacturers move to the 22 nm technology node and beyond, significantly thicker polymer layers must be deposited to adequately shrink the lithographically printed CDs to the targeted feature sizes. However, depositing thicker polymer layers by conventional methods often results in the formation of distorted features due to poor thickness uniformity, heavy striations, and distorted sidewall profiles. FIGS. 1A to 1C illustrate distorted features formed within the openings in a patterned layer 102 as a result of depositing a thicker polymer layer 106 on the patterned layer using conventional methods. FIG. 1A illustrates poor thickness uniformity of the polymer layer deposited along the sidewalls of the opening 104 where the thickness along the x-axis 110 is significantly less than the thickness along the y-axis 112. The resultant oval-shaped feature 108 is distorted from the original circular-shaped opening 104. Depositing a polymer layer with poor thickness uniformity between different openings in the patterned layer may also produce distorted features. FIG. 1B illustrates poor polymer thickness uniformity across contact holes 114 and 116 and a trench 118 where the thicknesses 120, 122 and 124 differ significantly from one another. The critical dimensions of the contact holes 114 and 116, and the trench 118 are therefore not reduced uniformly and the size of the features 126, 128 and 130 are distorted relative to one another. FIG. 1C illustrates a distorted feature 110 formed as a result of heavy striations 116 in the deposited polymer layer 106. FIG. 2 illustrates the cross-sectional view of a patterned layer 202 with openings 204 having distorted sidewall profiles 206 as a result of depositing a polymer layer 208 using conventional methods. The polymer layer 208 has poor thickness uniformity along the sidewalls of the openings, thereby forming a distorted ‘mushroom’ shaped sidewall profile rather the ideal straight sidewall profile. The distorted features shown in FIGS. 1A to 1C and FIG. 2 often cause device failures, reliability issues, and poor manufacturing yields.

Therefore, there is a need in the art for improved methods of polymer deposition for forming reduced critical dimensions.

### SUMMARY

Embodiments of the present invention include methods of polymer deposition for forming reduced critical dimensions.

In one embodiment, a method includes providing a substrate into a chamber, the substrate having a patterned layer disposed on an underlying layer formed thereon. The patterned layer includes a plurality of openings, each opening having a sidewall, a bottom, and a critical dimension. A gas mixture is provided into the chamber, the gas mixture having an etching gas and a polymer control gas. The polymer control gas includes a polymerizing fluorocarbon CₓF_{y} gas and a C—H bond containing gas. A plasma is formed with the gas mixture and a conformal polymer layer is deposited in the presence of the plasma on the patterned layer to form a reduced critical dimension in each opening. The reduced critical dimension is smaller than the corresponding critical dimension of the opening.

### BRIEF DESCRIPTION OF THE DRAWINGS

Embodiments of the present disclosure are illustrated by way of example, and not by way of limitation, in the figures of the accompanying drawings, in which:

FIGS. 1A to 1C illustrate the top views of a patterned layer having openings with distorted features as a result of depositing a polymer layer using conventional methods.

FIG. 2 illustrates the cross-section view of a patterned layer having openings with distorted features as a result of depositing a polymer layer using conventional methods.

FIG. 3 is a flowchart representing operations in a method of polymer deposition for forming reduced critical dimensions, in accordance with an embodiment of the present invention.

FIGS. 4A to 4C illustrate cross-sectional views representing various operations in a method of polymer deposition for forming reduced critical dimensions, in accordance with an embodiment of the present invention.

FIG. 5 is a flowchart representing operations in a method of polymer deposition for forming reduced critical dimensions, in accordance with an embodiment of the present invention.

FIGS. 6A to 6D are cross-sectional views illustrating a method of polymer deposition for forming reduced critical dimensions, in accordance with an embodiment of the present invention.

FIGS. 7A to 7D are cross-sectional views illustrating a method of polymer deposition for forming reduced critical dimensions, in accordance with an embodiment of the present invention.

FIGS. 8A and 8B are cross-sectional views illustrating a method of polymer deposition for forming reduced critical dimensions, in accordance with an embodiment of the present invention.

FIGS. 9A and 9B are top views of a patterned layer illustrating a method of polymer deposition for forming reduced critical dimensions, in accordance with an embodiment of the present invention.

FIG. 10 is a schematic cross-sectional diagram of an exemplary plasma system that may be used to practice embodiments of the present invention.

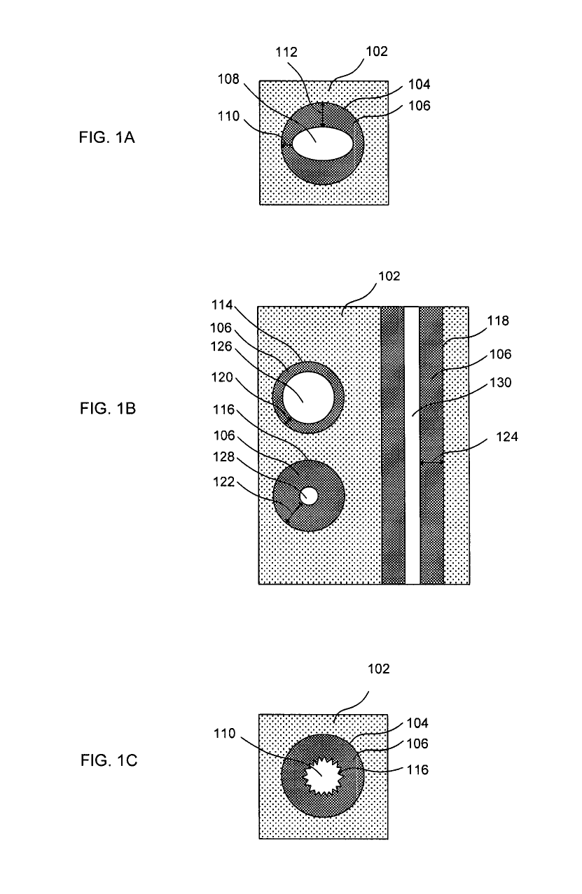

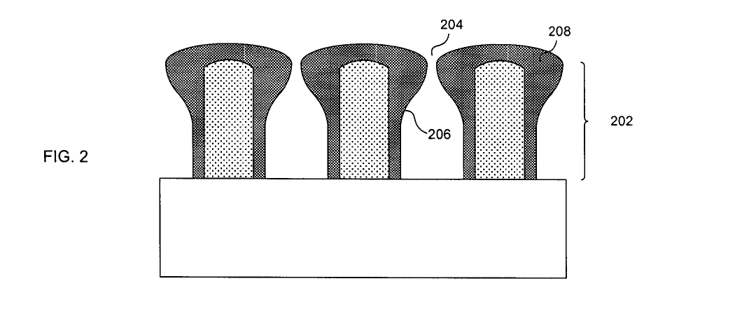

### DETAILED DESCRIPTION

Methods of polymer deposition for forming reduced critical dimensions (CD) are described. In the following description, numerous details are set forth. It will be apparent, however, to one skilled in the art, that the present invention may be practiced without these specific details. In other instances, well-known aspects, such as photo-lithography patterning and development for mask formation, are not described in detail to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

In integrated circuit fabrication, a conformal polymer layer may be deposited on a patterned layer having openings to form reduced CDs in the openings. As integrated circuit manufacturers continue to reduce feature sizes to achieve greater circuit density and higher performance, thicker polymer layers are required to form features with increasingly smaller reduced CDs. However, depositing a thicker polymer layer that can achieve a CD reduction of 30 nm or more presents problems of poor thickness uniformity, heavy striations in the polymer layer, and distorted sidewall profiles which may cause device failure and reliability issues. Therefore, depositing a striation-free polymer layer that has good thickness uniformity and produces straight sidewall profiles is critical in forming the small features necessary for fabricating next generation integrated circuits.

In accordance with one or more embodiments of the present invention, a method of polymer deposition for forming reduced CDs is disclosed. The method comprises providing a gas mixture that includes an etching gas and a polymer control gas to deposit a polymer layer on a patterned layer having openings. The polymer control gas includes a fluorocarbon CₓF_{y} gas and a C—H bond containing gas. In one such embodiment, the etching gas, the fluorocarbon CₓF_{y} gas, and the C—H bond containing gas are provided at flow rates sufficient to deposit a striation-free polymer layer on the top surface of the patterned layer and on the sidewalls of the openings with a negligible amount of polymer depositing on the bottoms of the openings. The etching gas and the polymer control gas may be provided at a ratio between about 8:1 and 20:1. The fluorocarbon CₓF_{y} gas and the C—H bond containing gas may be provided at a ratio between about 1:1 and 4:1. The polymer layer forms reduced critical dimensions within the openings where the reduced critical dimensions are smaller than the corresponding critical dimensions of the openings. The polymer layer also produces approximately smooth and straight sidewall profiles in the openings regardless of whether the sidewall profiles of the openings are straight or distorted. For trench openings, the polymer layer produces smooth edges regardless of the severity of edge roughness of the trench openings.

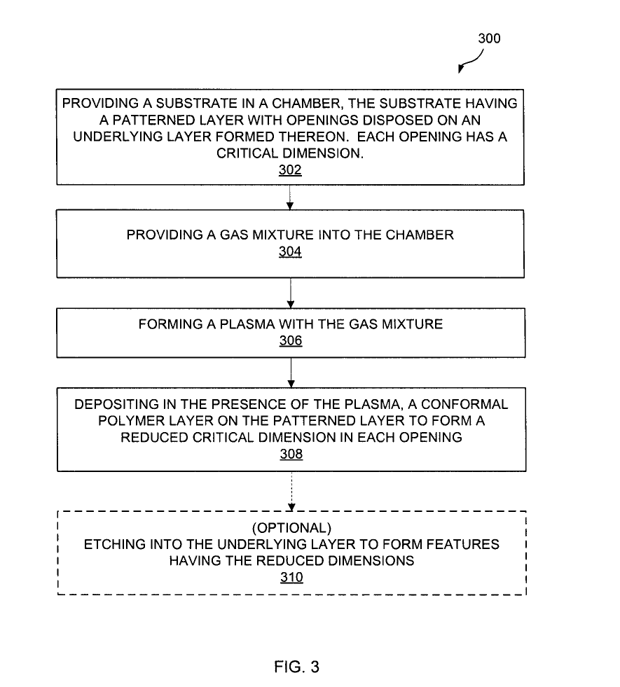

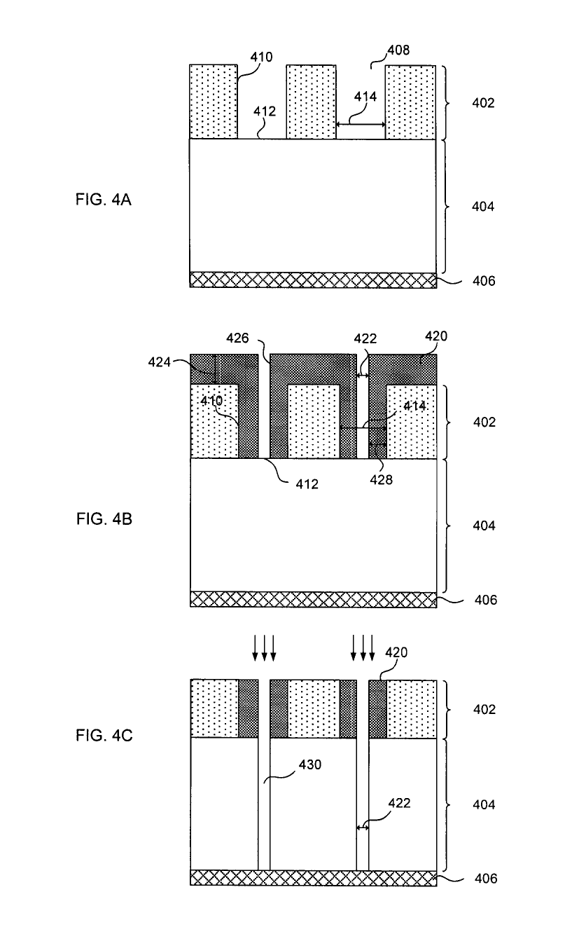

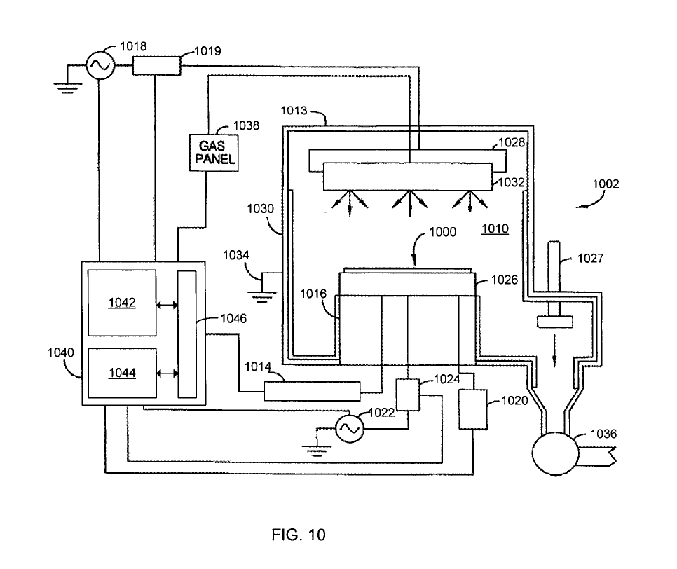

FIG. 3 is a flow chart 300 representing operations in a method of polymer deposition for forming reduced CDs, in accordance with an embodiment of the present invention. FIGS. 4A to 4C illustrate cross-sectional views representing operations in a method of polymer deposition for forming reduced CDs, in accordance with an embodiment of the present invention. The method begins at operation 302 by providing a substrate into a chamber. An example of a suitable chamber 1010 is illustrated in FIG. 10 and is described later in greater detail. Referring to FIG. 4A, the substrate 406 has a patterned layer 402 disposed on an underlying layer 404 formed thereon. The patterned layer 402 has openings 408, such as, but not limited to contact holes and trenches. When viewing top-down onto the patterned layer, contact holes are circular-shaped openings while trenches are long and narrow openings. Each opening 408 has a sidewall 410, a bottom 412, and a critical dimension 414. The patterned layer 402 may comprise of any material that is resistant to etching. The critical dimensions of the openings may be the smallest printable critical dimensions using optical lithography techniques. Recently, the smallest printable critical dimensions using optical lithography techniques is approximately 55 nm. In one embodiment, the patterned layer may include a photoresist layer patterned via a lithography or direct-write process. In another embodiment, the patterned mask may be a patterned hard mask layer, such as a hard mask layer selected from the group consisting of silicon dioxide (SiO2), silicon oxynitride (SiON), silicon nitride (SiN), silicon carbide (SiC), silicon nitride carbide (SiCN), amorphous silicon (α-Si), amorphous carbon (α-carbon), and a metal layer. In another embodiment, the patterned mask may include a DARC layer such as, but not limited to SiON and SiCN. In yet another embodiment, the patterned mask may be a composite layer comprising at least two materials selected from the group consisting of photoresist, bottom anti-reflective coating (BARC), dielectric anti-reflective coating (DARC), SiO2, SiON, SiN, SiC, SiCN, α-Si, and α-carbon.

Referring to FIG. 4A, the underlying layer 404 is where features necessary for the fabrication of integrated circuits or microelectromechanical systems (MEMS) (e.g., contacts, lines, trenches, etc.) may be formed by subsequent processes (e.g., etching, deposition, photolithography patterning etc). The underlying layer 404 may comprise of any material suitable for forming such features. In one embodiment, the underlying layer includes an anti-reflective coating (ARC) such as, but not limited to Bottom Anti-Reflective Coating (BARC) and Dielectric Anti-Reflective Coating (DARC). In another embodiment, the underlying layer includes a hard mask layer such as, but not limited to SiO₂, SiON, SiN, SiC, SiCN, α-Si, α-carbon, and metal. In another embodiment, the underlying layer includes a dielectric material such as, but not limited to undoped SiO₂, doped SiO₂, SiON, SiN, SiC, SiCN, SiOC, and a low-k dielectric layer. In another embodiment, the underlying layer includes a conductive material such as, but not limited to doped polysilicon, undoped polysilicon, Ti, TiN, W, WiSx, and Al. In a further embodiment, the underlying layer may be a composite layer including at least two layers selected from any of the materials described above.

Referring to FIG. 4A, the underlying layer is formed above the substrate 406. The substrate may comprise of any one of semiconductor substrates such as crystalline silicon or germanium. In one embodiment, the substrate 406 is comprised of a group III-V material such as, but not limited to, gallium nitride, gallium phosphide, gallium arsenide, indium phosphide, indium antimonide, indium gallium arsenide, aluminum gallium arsenide, indium gallium phosphide or a combination thereof. In another embodiment, the substrate 406 is glass. In a further embodiment, the substrate 406 is comprised of an epitaxial layer grown atop a distinct crystalline substrate (e.g. a silicon epitaxial layer grown atop a boron-doped silicon mono-crystalline substrate). The substrate 406 may also comprise an insulating layer (e.g., silicon dioxide, silicon nitride, silicon oxynitride and a high-k dielectric layer) in between a crystal substrate and an epitaxial layer to form, for example, a silicon-on-insulator substrate. In one embodiment, the substrate 406 may include other fabricated layers or structures such as field effect transistors, MEMS structures, electrical interconnects, insulating layers, and conductive wires.

At operation 304 in flowchart 300, a gas mixture is provided into the chamber. The gas mixture includes an etching gas and a polymer control gas. The etching gas may be a fluorocarbon gas with a high fluorine-to-carbon ratio (F:C) such as, but not limited to CF₄. The polymer control gas includes a polymerizing fluorocarbon gas and a C—H bond containing gas. In an embodiment, the polymerizing fluorocarbon gas comprises one or more compounds, each having a general formula CₓF_{y} where x=2-6 and y=2-8, such as, but not limited to C₄F₆, C₄F₈, C₂F₄, C₂F₆, C₃F₆, C₅F₈, CF₄, and C₆F₆. In a specific embodiment, the polymerizing fluorocarbon gas may be C₄F₆ and/or C₄F₈. The C—H bond containing gas comprises a compound having a general formula C₄F₆ where x=1-6, y=1-8, z=0-6, such as, but not limited to CH₃F, CH₂F₂, CHF₃, C₃H₃F₃, and C₂H₂F₆, CH₄, C₂H₄, and C₂H₆. In a specific embodiment, the C—H bond containing gas is CH₂F₂. In a particular embodiment, the polymer control gas includes a polymerizing fluorocarbon gas that is C₄F₆ and/or C₄F₈ and a C—H bond containing gas that is CH₂F₂.

The ratio of etching gas to polymer control gas provided into the chamber may be controlled to deposit a striation-free polymer layer on the patterned layer that has good thickness uniformity and produces straight sidewall profiles in the openings. A ratio of etching gas to polymer gas that is too low results in high polymer deposition rates and may cause polymer growth at the bottoms of the openings as well as polymer clogging at the top entrances of the openings. A ratio of etching gas to polymer gas that is too high results in excessive etching and may cause etch damage to the patterned layer and to the bottoms of the openings. In an embodiment, the ratio of etching gas to polymer gas is sufficiently high to prevent polymer growth at the bottoms of the openings and polymer clogging at the top entrances of the openings and is sufficiently low to prevent etch damage to the patterned layer and to the bottoms of the openings. In one embodiment, the flow rate ratio of etching gas to polymer control gas is at least 8:1. In another embodiment, the flow rate ratio of etching gas to polymer control gas is between 8:1 and 20:1. In a specific embodiment, the flow rate ratio of etching gas to polymer control gas is between 8:1 and 10:1. In one embodiment, the etching gas flow rate is between about 100 sccm and 300 sccm and the polymer control gas flow rate is between about 15 sccm and 90 sccm.

The ratio of polymerizing fluorocarbon gas and the C—H bond containing gas is regulated to deposit a striation-free polymer layer having good thickness uniformity. Providing a ratio of polymerizing fluorocarbon gas to C—H bond containing gas that is too high results in excessive polymer growth at the top entrances of the openings, thereby causing distorted ‘mushroom’ shaped sidewall profiles and polymer clogging at the tops of the openings. Providing a ratio of polymerizing fluorocarbon gas to C—H bond containing gas that is too low results in polymer growth at the bottoms of the openings, thereby preventing the underlying layer from being etched during subsequent etch processes. In an embodiment, the ratio of polymerizing fluorocarbon gas to C—H bond containing gas is sufficiently low to prevent distorted ‘mushroom’ shaped sidewall profiles and polymer clogging at the tops of the openings and is sufficiently high to prevent polymer growth at the bottoms of the openings. In one embodiment, the ratio of polymerizing fluorocarbon gas to C—H bond containing gas is between 1:1 and 4:1. In a specific embodiment, the ratio of polymerizing fluorocarbon gas to C—H bond containing gas is about 2:1.

Referring to operation 306 in flowchart 300, a plasma is formed with the gas mixture. The plasma may be formed by supplying one or more power sources to the chamber. In one embodiment, the plasma is formed by supplying a radio frequency (RF) bias power source. In a separate embodiment, the plasma is formed by supplying a RF bias power and no RF source power. The frequency and power of the RF bias power may be controlled to form a plasma that deposits a striation-free polymer layer that has good thickness uniformity and produces straight sidewall profiles in the openings. A sufficiently low RF bias power is necessary to form a plasma that predominately deposits polymer. Providing too high of a RF bias power forms a plasma that predominately etches rather than deposits polymer and causes etch damage to the patterned layer and to the underlying layer at the bottoms of the openings. In an embodiment, a sufficiently low RF bias power is supplied to form a plasma that does not cause etch damage to the patterned layer and to the underlying layer at the bottoms of the openings. In one embodiment, the RF bias power is supplied at between about 300 W and 700 W normalized to a 300 mm substrate. The frequency of the RF bias power is also controlled to deposit a striation-free polymer layer having good thickness uniformity. Supplying a RF bias power at too high of a frequency results in high plasma density, thereby causing a high polymer depositing rate and poor polymer thickness uniformity. Supplying a RF bias power at too low (e.g., 13.56 MHz) of a frequency results in high ion bombardment, thereby causing etch damage to the bottoms of the openings and to the patterned layer. In an embodiment, a RF bias power is supplied at a sufficiently low frequency to achieve good polymer thickness uniformity and at a sufficiently high frequency to prevent etch damage to the patterned layer and to the bottoms of the openings. In one embodiment, the low frequency bias power is supplied at a frequency between about 45 MHz and 75 MHz. In a specific embodiment, a 60 MHz low frequency generator delivers between about 300 W and 700 W of bias power to the plasma normalized to a 300 mm substrate.

During polymer deposition, a chamber pressure is generated to form a plasma capable of depositing a polymer layer that is striation-free and has good thickness uniformity in an embodiment. A chamber pressure that is too low forms a plasma that predominately etches and causes etch damage to the patterned layer and to the bottoms of the openings. An excessively high chamber pressure forms a plasma that deposits polymer at a high deposition rate and results in striations and poor thickness uniformity. In an embodiment, a sufficiently high chamber pressure is generated to form a plasma that does not cause etch damage to the patterned layer and to the bottoms of the openings. In an embodiment, a sufficiently low chamber pressure is generated to produce a plasma that deposits a striation-free polymer layer with good thickness uniformity. In a specific embodiment, a chamber pressure between about 80 mT and 120 mT is generated during polymer deposition. In an embodiment, a sufficiently high chamber pressure is generated and a sufficiently low RF bias power is provided to form a plasma that predominately deposits polymer on the patterned layer and does not cause etch damage to the patterned layer and to the bottoms of the openings. In a specific embodiment, a RF bias power between about 300 W and 700 W normalized to a 300 mm substrate is supplied and a chamber pressure between about 80 mT and 120 mT is generated during polymer deposition.

During polymer deposition, the substrate may be retained on a chuck (e.g., an electrostatic chuck) in the chamber. The temperature of the substrate within the chamber may be controlled by regulating the temperature of the chuck retaining the substrate. A lower substrate temperature promotes polymer deposition onto the substrate and results in a high deposition rate. In an embodiment, the chuck is controlled at a temperature sufficient to deposit a striation-free polymer layer on the patterned layer with good thickness uniformity. The chuck temperature may be controlled between about 0° C. and 60° C. In a particular embodiment, the chuck temperature is controlled between about 0° C. and 10° C.

Referring to operation 308 in flowchart 300 and the corresponding FIG. 4B, a conformal polymer layer 420 is deposited in the presence of the plasma on the patterned layer 402 to form a reduced CD 422 in each opening. The reduced CD 422 is smaller than the corresponding CD 414 of the opening. In one embodiment, the reduced CD 422 is at least 30 nm smaller than the corresponding CD 414 of the opening. In another embodiment, the reduced CD 422 is at least 45 nm smaller than the corresponding CD 414 of the opening. The polymer layer deposits on the top of the patterned layer 402 and the sidewalls 410 of the openings. A negligible amount of polymer is deposited on the bottoms 412 of the openings. The thickness 426 of the polymer layer on the top of the patterned layer is approximately double the thickness 428 of the polymer layer on the sidewalls of the openings. In an embodiment, the thickness 428 of the polymer layer is approximately uniform along the sidewall of each opening. In another embodiment, the thickness 428 of the polymer layer on the sidewalls of the openings may also be approximately uniform across the substrate. In addition, the deposited polymer layer is striation-free and produces straight sidewall profiles in the openings. In a particular embodiment, the deposited polymer layer forms reduced CDs in the openings that are at least 45 nm smaller than the CDs of the openings. In an embodiment, the deposited polymer layer forms reduced CDs in the openings that are at least 45 nm smaller than the CDs of the openings and the 3-sigma uniformity of the reduced CDs that correspond to the openings having approximately the same CDs is 1.7 nanometers or less across the substrate.

Referring to optional operation 310 and the corresponding FIG. 4C, the underlying layer 404 may be subsequently etched to form features 430 having the reduced CDs 422. The top of the conformal polymer layer 420 and may be eroded during such subsequent etch process to expose the patterned layer 402. The patterned layer 402 may also be eroding during the subsequent etch process, resulting in a reduced thickness. The subsequent etch process may be a dry etch process or a wet etch process. The subsequent etch process may be performed in the same chamber as the polymer deposition or in a different chamber. In a separate embodiment, optional operation 310 may be substituted with a different optional processing step. For example, the different optional processing step may be a deposition process (e.g.: chemical vapor deposition, physical vapor deposition, electro-plating, electroless plating, etc.) that deposits a material such as a metal, a semiconductor, or an insulator at the bottom 412 of the openings on the underlying layer 404.

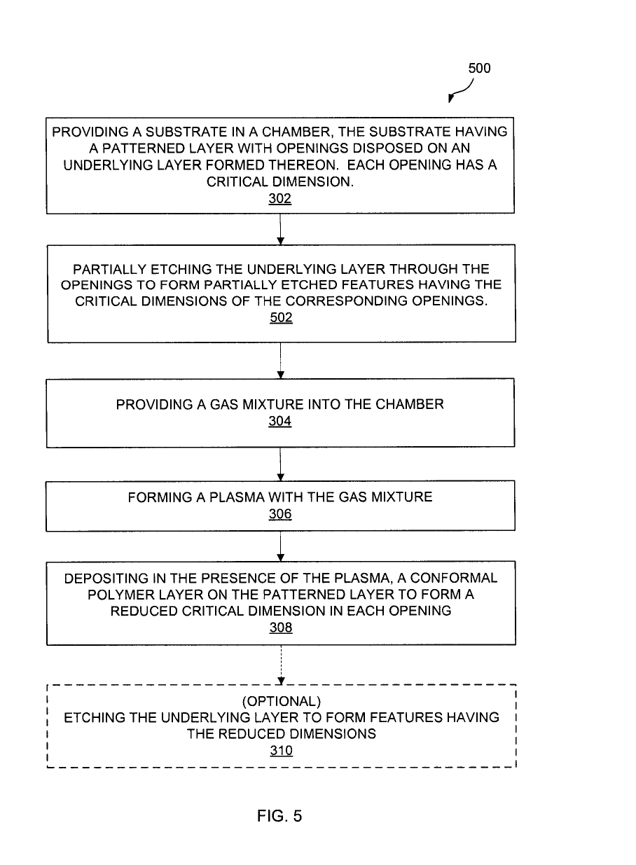

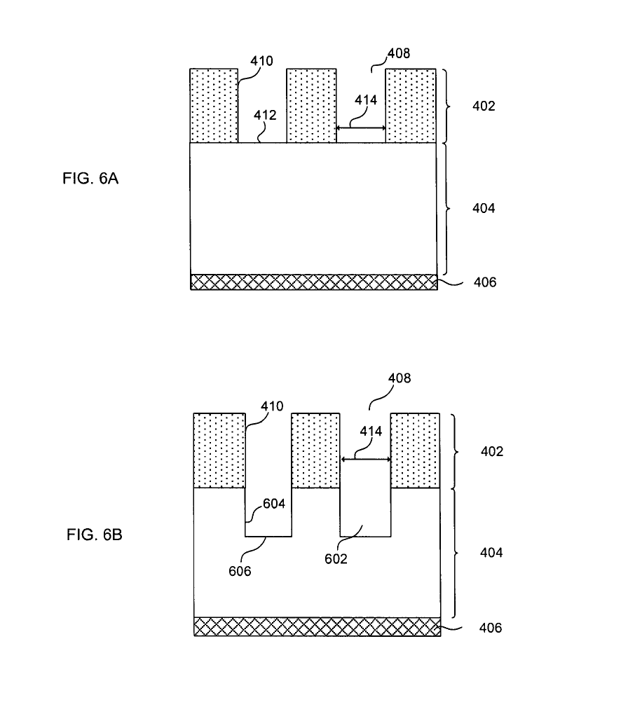

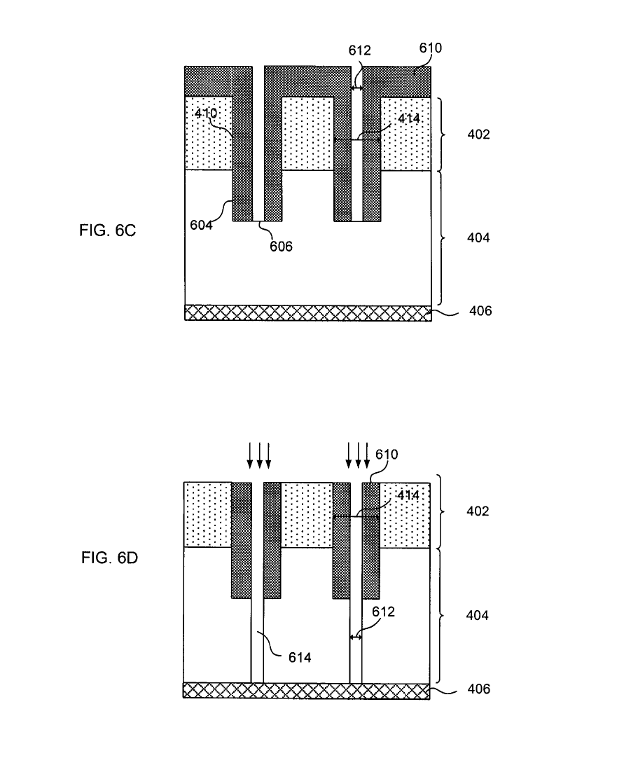

In another embodiment of the present invention, the underlying layer 404 may be partially etched through the openings 408 prior to operation 304 in flowchart 300 where a gas mixture is provided into the chamber. FIG. 5 is a flowchart 500 representing operations in a method of polymer deposition for forming reduced CDs according to one such embodiment. FIGS. 6A to 6C are corresponding cross-sectional views illustrating a method of polymer deposition for forming reduced CDs according to one such embodiment. The method begins at operation 302 in flowchart 500 by providing a substrate 406 into a chamber. The substrate 406 has a patterned layer 402 disposed on an underlying layer 404 formed thereon as shown in FIG. 6A. The patterned layer 402 has openings 408 where each opening has a sidewall 410, a bottom 412, and a critical dimension 414. Referring to operation 502 in flowchart 500 and the corresponding FIG. 6B, the underlying layer 404 may be partially etched through the openings 408 to form partially etched features 602 having the CDs 414 of the corresponding openings 408. Each partially etched feature 602 has a sidewall 604 and a bottom 606. The sidewall 604 of each partially etched feature is roughly in alignment with the sidewall 410 of the corresponding opening 408. The critical dimension 608 of each partially etched feature is approximately equal to the critical dimension 414 of the corresponding opening. Referring to operations 304, 306, and 308 in flowchart 500, a gas mixture is provided into the chamber, a plasma is formed with the gas mixture, and a conformal polymer layer 610 is deposited on the patterned layer 402 in the presence of the plasma. The deposition process for the polymer layer, including the composition of the gas mixture, the chamber pressure generated, and the power provided to form the plasma has been previously described. The polymer layer 610 deposits on the top of the patterned layer, the sidewalls 410 of the openings 408, and the sidewalls 604 of the partially etched features 602 as shown in FIG. 6C. A negligible amount of polymer deposits on the bottoms 606 of the partially etched features. The polymer layer 610 forms reduced CDs 612 in the openings 408 where the reduced CDs 612 are smaller than the corresponding CDs 414 of the openings 408. Referring to optional operation 310 and corresponding FIG. 6D, the underlying layer 404 may be subsequently etched to form features 614 in the underlying layer having the reduced CDs 612. The top of the polymer layer 610 and may be eroded during such subsequent etch process to expose the patterned layer 402. The patterned layer 402 may also be eroding during the subsequent etch process, resulting in a reduced thickness.

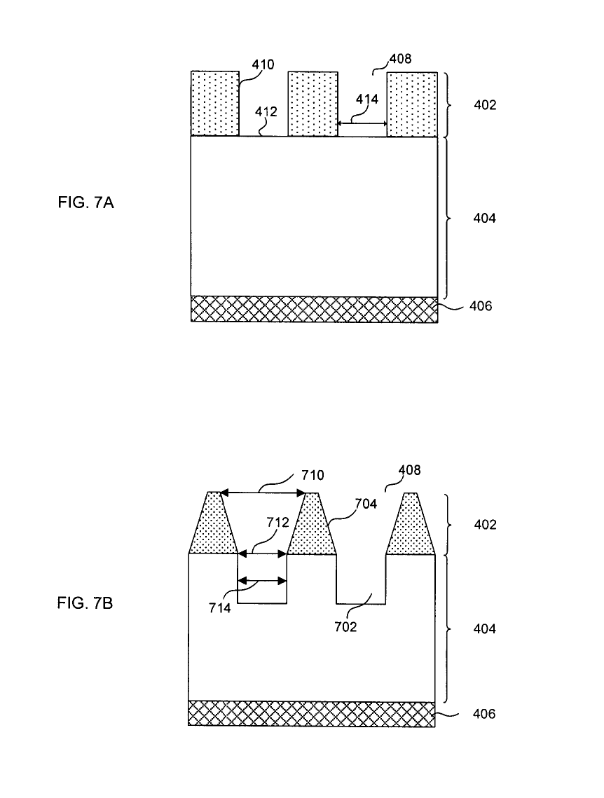

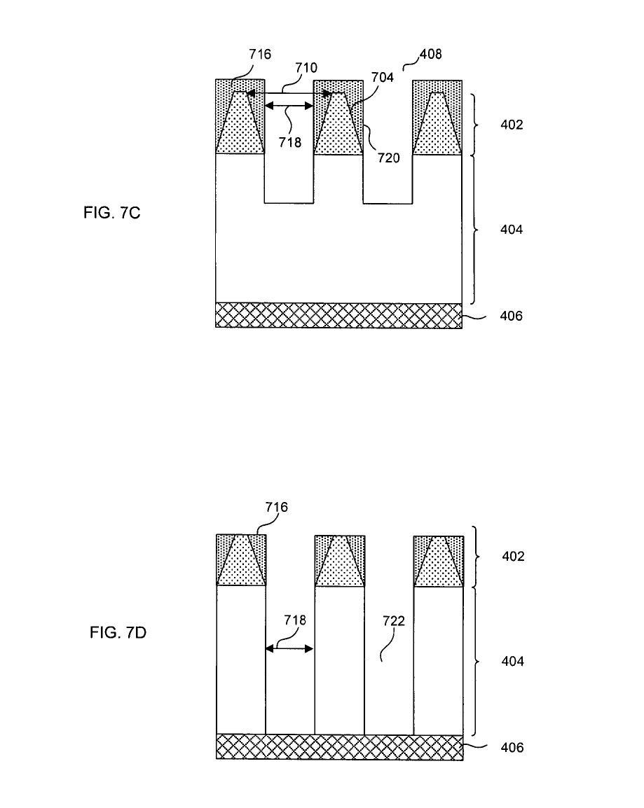

In a further embodiment, the patterned layer 402 may be eroded during the partial etching of the underlying layer 404 in operation 502 of flowchart 500 and results in the openings 408 having distorted sidewalls 704. FIGS. 7A and 7D are a sequence of cross-sectional views illustrating a method of polymer deposition for forming reduced CDs according to one such embodiment. The method begins at operation 302 in flowchart 500 by providing a substrate 406 into a chamber. The substrate 406 has a patterned layer 402 disposed on an underlying layer 404 formed thereon as shown in FIG. 7A. The patterned layer 402 has openings 408 where each opening has a sidewall 410, a bottom 412, and a critical dimension 414. Referring to operation 502 in flowchart 500 and the corresponding FIG. 7B, the underlying layer 404 may be partially etched through the openings 408 to form partially etched features 702. The patterned layer 402 is eroded during the partial etching of the underlying layer 404 and results in the openings 408 having distorted sidewalls 704. The distorted sidewalls 704 may be significantly tapered such that the CD 710 at the top of each opening is significantly larger than the CD 712 at the bottom of the opening. Each partially etched feature 702 has a CD 714 that is approximately equal to the CD 712 at the bottom of the corresponding opening. Referring to operations 304, 306, and 308 in flowchart 500, a gas mixture is provided into the chamber, a plasma is formed with the gas mixture, and a conformal polymer layer 716 is deposited on the patterned layer 402 in the presence of the plasma. The deposition process for the polymer layer, including the composition of the gas mixture, the chamber pressure generated, and the power provided to form the plasma has been previously described. The polymer layer 716 mainly deposits on the top of the patterned layer 402 and on the distorted sidewalls 704 of the openings as shown in FIG. 7C. The polymer layer 716 forms reduced CDs 718 in the openings where the reduced CDs 718 are smaller than the corresponding CDs 710 at tops of the openings. The polymer layer 716 also straightens the distorted sidewalls 704 by forming straight sidewall profiles 720 in the openings. Referring to optional operation 310 and corresponding FIG. 7D, the underlying layer 404 may be subsequently etched to form features 722 in the underlying layer 404 having the reduced CDs 718. The polymer layer 716 protects the patterned layer 402 during subsequent etch processes, thereby enhancing the etch selectivity of the patterned layer 402. The enhanced etch selectivity provided by the polymer layer 716 prevents the partially etched features 702 and the features 722 from being distorted during subsequent etch processes.

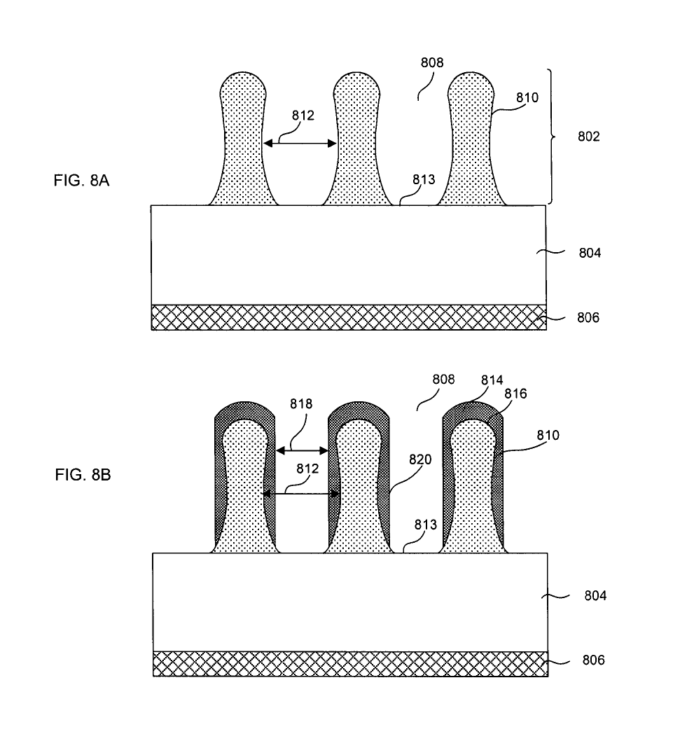

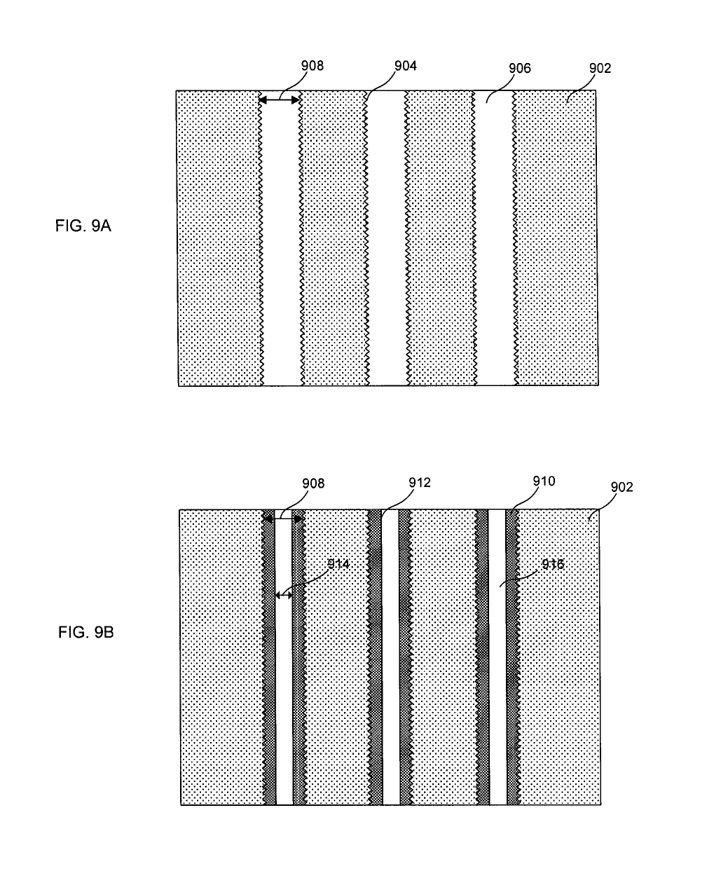

In another embodiment, the patterned layer may be a patterned photoresist layer with openings having distorted sidewall profiles and the deposited polymer layer may produce straight sidewall profiles in the openings. FIGS. 8A and 8B are a sequence of cross-sectional views illustrating a method of polymer deposition for forming reduced CDs according to an embodiment of the present invention. The patterned layer comprises a patterned photoresist layer 802 (e.g., DUV photoresist) having openings 808 with CDs 812, as shown in FIG. 8A. Each opening 808 has a distorted sidewall 810 having a ‘mushroom’ shape profile and a bottom 813. Referring to FIG. 8B, a polymer layer 814 is deposited on the patterned photoresist layer 802 according to an embodiment of the invention. The polymer layer 814 deposits on the top of the patterned photoresist layer and on the distorted sidewalls 810 of the openings. A negligible amount of polymer deposits on the bottoms 813 of the openings. The polymer layer 814 forms reduced CDs 818 in the openings where the reduced CDs 818 are smaller than the corresponding CDs 812 of the openings. In addition, the polymer layer 814 forms straight sidewall profiles 820 in the openings 808, thereby improving the sidewall profile of opening.

In another embodiment, the openings in the patterned layer may have significant edge roughness and the deposited polymer layer may produce features having improved edge roughness. FIGS. 9A and 9B are a sequence of top views of a patterned layer 902 illustrating a method of polymer deposition for forming reduced CDs according to an embodiment of the present invention. Referring to FIG. 9A, the patterned layer 902 may comprise of a patterned photoresist layer (e.g., DUV photoresist) having openings 906 (e.g., contact holes and trenches). The openings 906 have CDs 908 and significant edge roughness 904. Referring to FIG. 9B, a polymer layer 910 is deposited on the patterned layer according to one embodiment of the present invention. The polymer layer 910 forms reduced CDs 914 in the openings where the reduced CDs are smaller than the corresponding CDs 908 of the openings. In addition, the polymer layer forms features 916 in the openings having smooth edges 912, thereby resulting in improved edge roughness.

The polymer deposition method described herein may be performed in any suitably adapted plasma system such as the Applied Centura® Enabler etch system, available from Applied Materials of Santa Clara, Calif., USA or the Applied Centura® Producer Etch system with a twin chamber design, also available from Applied Materials of Santa Clara, Calif., USA. It is contemplated that suitably adapted plasma systems, including those available from other manufacturers, may also be utilized to practice the present invention.

FIG. 10 depicts a schematic, cross-sectional diagram of an exemplary plasma system 1002 suitable to perform polymer deposition for forming reduced CDs according to embodiments of the present invention. In one embodiment, the plasma system 1002 includes a chamber 1010 connected to an electrical ground 1034. The chamber 1010 is a high vacuum vessel that is coupled through a throttle valve 1027 to a vacuum pump 1036. The chamber 1010 includes a support pedestal 1016 and a showerhead 1032. The support pedestal 1016 is disposed below the showerhead 1032 in a spaced-apart relation. The support pedestal 1016 is coupled to a radio frequency (RF) bias power source 1022 through a matching network 1024. In one embodiment, the bias power source 1022 has a low frequency, such as about 60 MHz. The support pedestal 1016 may include a chuck 1026, such as an electrostatic chuck (ESC), for retaining a substrate 1000 during processing. The chuck may be powered by a DC power supply 1020. The temperature of the chuck 1026 may be regulated during processing by heating or cooling the chuck with a heat exchanger 1014. The temperature of the substrate 1000 is at least partially controlled by regulating the temperature of the chuck 1026.

The showerhead 1032 is mounted to a lid 1013 of the chamber 1010. A gas panel 1038 is fluidly coupled to a plenum (not shown) defined between the showerhead 1032 and the lid 1013. Processing gases are provided from the gas panel 1038 to the plenum. The processing gases intermix in the plenum before entering into the chamber 1010 as a gas mixture through a plurality of orifices in the showerhead 1032. Mass flow controllers (not shown) in the gas panel 1038 may regulate the volumetric flow rates of the processing gases provided from the gas panel 1038 into the chamber 1010. The showerhead 1032 and/or an upper electrode 1028 positioned proximate thereto may also be coupled to an RF source power 1018 through an impedance transformer 1019 (e.g., a quarter wavelength matching stub).

In an embodiment of the present invention, a controller 1040 is coupled to various components of the plasma system and controls the plasma system to perform the processes of the present invention. The controller regulates the chamber pressure by controlling the mass flow controllers in the gas panel 1038 and the throttle valve 1027. The controller regulates the processing gas flow rates and the ratios of the different gases provided into the chamber by controlling the mass flow controllers in the gas panel 1038. The controller sets the magnitudes and the frequencies of the RF source power and RF bias power provided into the chamber by controlling the RF source power 1018 and RF bias power 1022 sources. The controller also regulates the temperature of the chuck 1026 by controlling the heat exchanger 1014.

The controller includes a processor 1046 in communication with memory 1042, and support circuits 1050. The processor may be one or more general-purpose processing devices such as a microprocessor, a central processing unit (CPU), or the like. The memory 1042 may be any computer-readable medium, such as, but not limited to random access memory (RAM), read only memory (ROM), floppy disk, hard disk, or any other form of digital storage, local or remote to the plasma system 1002 or processor 1046. The support circuits 1046 are coupled to the processor 1046 for supporting the processor 1046 in a conventional manner. These circuits include cache, power supplies, clock circuits, input/output circuitry and subsystems, and the like. The memory 1042 may include a machine-accessible storage medium such as a computer-readable storage medium on which is stored one or more sets of program instructions (e.g., software routine) embodying any one or more of the methodologies or functions of the present invention described herein. The one or more sets of program instructions stored in the memory 1042, when executed by the processor 1044, causes the plasma system 1002 to perform any one or more of the methods of polymer deposition to form reduced CDs as described herein.

In accordance with an embodiment of the present invention, a machine-accessible storage medium has a set of machine executable instructions stored thereon which, when executed by a controller, cause a suitable plasma etch system to perform a method of polymer deposition for forming reduce CDs. The method includes providing a substrate in a chamber, the substrate having a patterned layer disposed on an underlying layer formed thereon. The patterned layer includes a plurality of openings, each opening having a sidewall, a bottom, and a critical dimension. A gas mixture is provided into the chamber, the gas mixture having an etching gas and a polymer control gas. The polymer control gas includes a polymerizing fluorocarbon CxFy gas and a C—H bond containing gas. A plasma is formed with the gas mixture and a conformal polymer layer is deposited in the presence of the plasma on the patterned layer to form a reduced critical dimension in each opening. The reduced critical dimension is smaller than the corresponding critical dimension of the opening.

What is claimed is:

1. A method comprising:
providing a substrate into a chamber, said substrate having a patterned layer disposed on an underlying layer formed thereon, wherein the patterned layer includes a plurality of openings, each opening having a sidewall, a bottom, and a critical dimension;
providing a gas mixture into the chamber, said gas mixture having an etching gas and a polymer control gas, wherein the polymer control gas includes a polymerizing fluorocarbon CₓF_{y} gas and a C—H bond containing gas;
forming a plasma with the gas mixture; and,
depositing in the presence of the plasma, a conformal polymer layer on the patterned layer to form a reduced critical dimension in each opening, wherein the reduced critical dimension is smaller than the corresponding critical dimension of the opening.

2. The method of claim 1, wherein the polymerizing fluorocarbon gas is provided at a ratio of between about 1:1 and 4:1 to the C—H bond containing gas.

3. The method of claim 2, wherein the ratio of the polymerizing fluorocarbon gas to the C—H bond containing gas is about 2:1.

4. The method of claim 2, wherein the polymerizing fluorocarbon gas has a general formula CₓF_{y} where x=2-6 and y=2-8.

5. The method of claim 4, wherein the C—H bond containing gas has a general formula CₓH_{y}F_{z} where x=1-6, y=1-8, z=0-6.

6. The method of claim 2, wherein the polymerizing fluorocarbon gas is C₄F₆ and/or C₄F₈.

7. The method of claim 2, wherein the C—H bond containing gas is CH₂F₂.

8. The method of claim 2, wherein the C—H bond containing gas is CH₂F₂ and the polymerizing fluorocarbon gas is C₄F₆ and/or C₄F₈.

9. The method of claim 1, wherein the etching gas is CF₄,

10. The method of claim 1, wherein the ratio of etching gas flow to polymer control gas flow is at least 8:1.

11. The method of claim 1, further comprising providing a RF bias power source between about 300 W and 700 W normalized to a 300 mm substrate.

12. The method of claim 1, further comprising providing a RF bias power source having a frequency of between about 45 MHz and 75 MHz.

13. The method of claim 1, further comprising generating a chamber pressure between about 80 mT and 120 mT.

14. The method of claim 1, wherein the substrate is retained on a chuck in the chamber and the chuck is regulated at a temperature between about 0° C. and 60° C.

15. The method of claim 1, further comprising partially etching, prior to providing the gas mixture into the chamber, the underlying layer through the plurality of openings to form a plurality of partially etched features having the critical dimensions of the corresponding openings.

16. The method of claim 1, wherein the reduced critical dimensions are at least 45 nm smaller than the corresponding critical dimensions of the openings.

17. The method of claim 16, wherein the 3-sigma uniformity of the reduced CDs that correspond to the openings having approximately the same CDs is 1.7 nanometers or less across the substrate.

18. The method of claim 1, wherein the sidewall of an opening in the patterned layer has a tapered profile and the polymer layer produces a straight sidewall profile in the openings.

19. The method of claim 1, wherein the polymer layer increases the etch selectivity of the patterned layer.

20. The method of claim 1, wherein the patterned layer includes an opening having significant edge roughness and the polymer layer produces features in the openings having improved edge roughness.

21. The method of claim 1, wherein a sufficiently high chamber pressure is generated and a sufficiently low RF bias power is provided to form a plasma that predominately deposits polymer on the patterned layer and does not cause etch damage to the patterned layer and to the bottoms of the openings.

22. A method comprising:
providing a substrate into a chamber, said substrate having a patterned layer disposed on an underlying layer formed thereon, wherein the patterned layer includes a plurality of openings, each opening having a sidewall, a bottom, and a critical dimension;
providing a gas mixture into the chamber, said gas mixture having an etching gas and a polymer control gas, wherein the polymer control gas includes a polymerizing fluorocarbon CₓF_{y} gas and a C—H bond containing gas, and wherein the polymerizing fluorocarbon gas is provided at a ratio of between about 1:1 and 4:1 to the C—H bond containing gas;
providing into the chamber a RF bias power source at a frequency of approximately 60 MHz;
forming a plasma with the gas mixture; and,
depositing in the presence of the plasma, a conformal polymer layer on the patterned layer to form a reduced critical dimension in each opening, wherein the reduced critical dimension is smaller than the corresponding critical dimension of the opening.

23. The method of claim 22, wherein the polymerizing fluorocarbon gas is C₄F₆ and/or C₄F₈.

24. The method of claim 22, wherein the C—H bond containing gas is CH₂F₂.

25. The method of claim 22, wherein the C—H bond containing gas is CH₂F₂ and the polymerizing fluorocarbon gas is C₄F₆ and/or C₄F₈.

26. A method comprising:
providing a substrate into a chamber, said substrate having a patterned layer disposed on an underlying layer formed thereon, wherein the patterned layer includes a plurality of openings, each opening having a sidewall, a bottom, and a critical dimension;
providing a gas mixture into the chamber, said gas mixture having an etching gas and a polymer control gas, wherein the etching gas is CH₄ and the polymer control gas includes a polymerizing fluorocarbon gas and a C—H bond containing gas, wherein the polymerizing fluorocarbon gas is C₄F₆ and/or C₄F₈ and the C—H bond containing gas is CH₂F₂, and wherein the polymerizing fluorocarbon gas is provided at a ratio of 2:1 to the CH₂F₂ gas;
generating a chamber pressure of about 100 mT during polymer deposition;
retaining the substrate on a chuck in the chamber, wherein the chuck is regulated at a temperature between about 0° C. and 60° C.;
providing into the chamber a RF bias power source between about 300 W and 700 W at a frequency of approximately 60 MHz normalized to a 300 mm substrate;
forming a plasma with the gas mixture; and,
depositing in the presence of the plasma, a conformal polymer layer on the patterned layer to form a reduced critical dimension in each opening, wherein the reduced critical dimension is smaller than the corresponding critical dimension of the opening.
